(19) United States
(12) Patent Application Publication
(10) Pub. No.: US 2024/0401236 A1
(43) Pub. Date: Dec. 5, 2024

(54) ALN SINGLE CRYSTAL SUBSTRATE AND DEVICE

(71) Applicant: NGK INSULATORS, LTD., Nagoya-shi (JP)

(72) Inventors: Hiroharu KOBAYASHI, Kasugai-shi (JP); Hirohisa OGAWA, Kitanagoya-shi (JP); Morimichi WATANABE, Nagoya-shi (JP)

(21) Appl. No.: 18/798,950

(22) Filed: Aug. 9, 2024

Related U.S. Application Data
(63) Continuation of application No. PCT/JP2022/013983, filed on Mar. 24, 2022.

(51) Int. Cl. C30B 29/40

(52) U.S. Cl. CPC C30B 29/403

(57) ABSTRACT

There is provided an AlN single-crystal substrate containing a carbon atom and a rare earth atom as impurities, and satisfies a relation: 0.0010<C_{RE}/C_{C}<0.2000, wherein C_{C} is a carbon atom concentration (atoms/cm³) and C_{RE} is a rare earth atom concentration (atoms/cm³) in the AlN single-crystal substrate.

### CROSS-REFERENCE TO RELATED APPLICATIONS

This application is a continuation application of PCT/JP2022/013983 filed Mar. 24, 2022, the entire contents of which are incorporated herein by reference.

### BACKGROUND OF THE INVENTION

### 1. Field of the Invention

The present invention relates to an AlN single-crystal substrate and a device comprising the AlN single-crystal substrate.

### 2. Description of the Related Art

Aluminum nitride (AlN) single crystals have recently attracted attention as base substrates for deep ultraviolet light emitting elements using AlN-based semiconductors. For example, AlN, AlGaN, and the like are used as AlN-based semiconductors. These AlN-based semiconductors have a direct band gap structure, which makes them suitable for light-emitting devices and applicable to light emitting diodes (LEDs) and laser diodes (LDs) in the deep ultraviolet region usable for applications such as disinfection.

In such light-emitting devices, to achieve high transmittance in the ultraviolet region, it is desirable that the impurity concentration in the base substrate is low. For example, Patent Literature 1 (JP6080148B) discloses an AlN single crystal comprising an oxygen atom and a carbon atom, wherein the oxygen atom concentration is 5×10¹⁷ cm⁻³ or more and 5×10¹⁸ cm⁻³ or less, and the carbon atom concentration is 4×10¹⁷ cm⁻³ or more and 4×10¹⁸ cm⁻³ or less, and thus, has an oxygen atom concentration higher than the carbon atom concentration. This literature discloses that in order to reduce the impurity content, advanced control or a special apparatus is required during single-crystal growth; however, the above-described single crystal in which the oxygen atom and carbon atom concentrations have been controlled has good transparency to ultraviolet light. Patent Literature 2 (JP2009-78971A) discloses an AlN single-crystal substrate having an AlN composition, a total impurity density of 1×10¹⁷ cm⁻³ or less, and an absorption coefficient of 50 cm⁻¹ or less in a total wavelength range of 350 to 780 nm.

Additionally, regarding impurities in an AlN single crystal, Patent Literature 3 (JP4811082B) discloses an n-type AlN crystal having a structure in which a portion of Al atoms in the AlN crystal have been replaced by a group IIIa element and/or a group IIIb element, and one of adjacent N atoms has been simultaneously replaced by an O atom, wherein the group IIIa element and/or the group IIIb element is one or more elements selected from the group consisting of Y, Sc, La, Ce, and Ga. This literature describes the relationship between the oxygen concentration and the total concentration of the group IIIa element and/or the group IIIb element. Patent Literature 4 (JP6932995B) discloses an AlN single crystal having a wurtzite-type crystal structure and having a boron content of 0.5 ppm by mass or more and 251 ppm by mass or less.

### CITATION LIST

### Patent Literature

Patent Literature 1: JP6080148B
Patent Literature 2: JP2009-78971A
Patent Literature 3: JP4811082B
Patent Literature 4: JP6932995B

### SUMMARY OF THE INVENTION

As described above, a possible solution to control the properties of an AlN single crystal, such as achieving high deep-ultraviolet transmittance and n-type conduction, may be to control the relationship of impurity contents in the AlN single crystal. However, AlN single-crystal substrates as disclosed in Patent Literatures 1 to 4 have the drawback of being likely to have chipping (defects including chips and cracks) when processed (such as ground, polished, or cut), resulting in a reduced yield. Therefore, it is desirable to reduce chipping of AlN single-crystal substrates during processing of the AlN the single-crystal substrates.

The prevent inventors have now found that when an AlN single-crystal substrate satisfies a predetermined relation concerning the concentration ratio between carbon atoms and rare earth atoms as impurities, the AlN single-crystal substrate is less likely to have chipping when processed (such as ground, polished, or cut).

Therefore, it is an object of the present invention to provide an AlN single-crystal substrate that is less likely to have chipping when processed (such as ground, polished, or cut).

According to an aspect of the present invention, there is provided an AlN single-crystal substrate comprising a carbon atom and a rare earth atom as impurities, the AlN single-crystal substrate satisfying a relation:

0.0010<C_{RE}/C_{C}<0.2000
wherein C_{C} is a carbon atom concentration (atoms/cm³) and C_{RE} is a rare earth atom concentration (atoms/cm³) in the AlN single-crystal substrate.

According to another aspect of the present invention, there is provided a device comprising the AlN single-crystal substrate.

### BRIEF DESCRIPTION OF THE DRAWINGS

FIG. 1 is a schematic cross-sectional view showing the structure of a heat treatment apparatus used to prepare AlN raw material powder.

FIG. 2 is a schematic cross-sectional view showing the structure of a crystal growth apparatus used in a sublimation method.

### DETAILED DESCRIPTION OF THE INVENTION

### AlN Single-Crystal Substrate

An AlN single-crystal substrate according to the present invention comprises a carbon atom and a rare earth atom as impurities. This AlN single-crystal substrate satisfies a relation: 0.0010<C_{RE}/C_{C}<0.2000, wherein C_{C} is a carbon atom concentration (atoms/cm³) and C_{RE} is a rare earth atom concentration (atoms/cm³) in the AlN single-crystal substrate. When the AlN single-crystal substrate thus satisfies the predetermined relation concerning the concentration ratio between carbon atoms and rare earth atoms as impurities, the AlN single-crystal substrate is less likely to have chipping when processed (such as ground, polished, or cut). Therefore, by subjecting such an AlN single-crystal substrate to processing, the AlN single-crystal substrate can be manufactured at a high yield. That is, as described above, the conventional AlN single-crystal substrates have the drawback of being likely to have chipping when processed (such as ground, polished, and cut), resulting in a reduced yield. In this respect, the AlN single-crystal substrate of the present invention can advantageously overcome the aforementioned drawback.

While the AlN single-crystal substrate of the present invention satisfies the relation 0.0010<C_{RE}/C_{C}<0.2000, concerning the carbon atom concentration C_{C} and the rare earth atom C_{RE}, the lower limit of C_{RE}/C_{C} is preferably 0.0020<C_{RE}/C_{C}, and more preferably 0.0030<C_{RE}/C_{C}. In this manner, the higher the lower limit, the more the occurrence of cracks among chipping can be reduced. The upper limit of C_{RE}/C_{C} is preferably C_{RE}/C_{C}<0.1000, and more preferably C_{RE}/C_{C}<0.0100. In this manner, the lower the upper limit, the more the occurrence of chips among chipping can be reduced. When the AlN single-crystal substrate satisfies such relations, it is less likely to have chipping when processed (such as ground, polished, or cut). Moreover, by subjecting such an AlN single-crystal substrate to processing, the AlN single-crystal substrate can be manufactured at a higher yield.

The AlN single-crystal substrate may comprise an oxygen atom as an impurity. In this case, the AlN single-crystal substrate preferably satisfies a relation 4.5×10¹⁸<C_{O}−C_{C}<9.0×10²¹, more preferably satisfies a relation 1.0×10¹⁹<C_{O}−C_{C}<9.0×10²⁰, and still more preferably satisfies a relation 1.0×10¹⁹<C_{O}−C_{C}<2.0×10²⁰, wherein C_{O} is an oxygen atom concentration (atoms/cm³) in the AlN single-crystal substrate.

Moreover, when the AlN single-crystal substrate comprises an oxygen atom as an impurity, the AlN single-crystal substrate preferably satisfies relations: 4.0×10¹⁸<C_{C}<4.0×10²¹, 4.0×10¹⁸<C_{O}<4.0×10²¹, and 1.0×10¹⁶<C_{RE}<1.0×10¹⁹, wherein C_{O} is an oxygen atom concentration (atoms/cm³) in the AlN single-crystal substrate; more preferably satisfies relations: 1.0×10¹⁹<C_{C}<4.0×10²⁰, 1.0×10¹⁹<C_{O}<8.0×10²⁰, and 1.0×10¹⁷<C_{RE}<1.0×10¹⁸; and still more preferably satisfies relations: 5.0×10¹⁹<C_{C}<1.0×10²⁰, 5.0×10¹⁹<C_{O}<5.0×10²⁰, and 2.0×10¹⁷<C_{RE}<7.0×10¹⁷.

Thus, the AlN single-crystal substrate contains a carbon atom and a rare earth atom as impurities, and preferably also contains an oxygen atom as an impurity. Concerning the concentration of each of the atoms in the AlN single-crystal substrate, the carbon atom concentration C_{C} (atoms/cm³) is preferably 4.0×10¹⁸<C_{C}<4.0×10²¹, more preferably 1.0×10¹⁹<C_{C}<4.0×10²⁰, and still more preferably 5.0×10¹⁹<C_{C}<1.0×10²⁰. The oxygen atom concentration C_{O} (atoms/cm³) is preferably 4.0×10¹⁸<C_{O}<4.0×10²¹, more preferably 1.0×10¹⁹<C_{O}<8.0×10²⁰, and still more preferably 5.0×10¹⁹<C_{O}<5.0×10²⁰. The rare earth atom concentration C_{RE} (atoms/cm³) is preferably 1.0×10¹⁶<C_{RE}<1.0×10¹⁹, more preferably 1.0×10¹⁷<C_{RE}<1.0×10¹⁸, and still more preferably 2.0×10¹⁷<C_{RE}<7.0×10¹⁷.

Examples of the rare earth atom contained as an impurity in the AlN single-crystal substrate include Y, La, Sm, Ce, Yb, Eu, and Dy atoms, as well as combinations thereof. The rare earth atom is preferably an Y atom, a Ce atom, an Yb atom, a Sm atom, or a combination thereof, from the viewpoint of reducing chipping, and is more preferably an Y atom.

The AlN single-crystal substrate preferably has a surface area of more than 75 mm² and less than 18500 mm², and more preferably more than 300 mm² and less than 8200 mm². The AlN single-crystal substrate preferably has a thickness of more than 0.10 mm and less than 1.00 mm, and more preferably more than 0.30 mm and less than 0.70 mm.

The AlN single-crystal substrate according to the present invention is preferably an oriented layer that is oriented in both the c- and a-axis directions, and may contain a mosaic crystal. The mosaic crystal refers to a crystal that does not have distinct grain boundaries but is an aggregation of crystals whose crystal orientation slightly deviates from one or both of the c- and a-axes. Such an oriented layer has a structure in which the crystal orientation is substantially aligned with a substantially normal direction (c-axis direction) and an in-plane direction (a-axis direction). Such a structure allows a semiconductor layer with an excellent quality, particularly an excellent orientation, to be formed on the oriented layer. That is, when forming a semiconductor layer on the oriented layer, the crystal orientation of the semiconductor layer substantially matches the crystal orientation of the oriented layer. Therefore, a semiconductor film formed on the AlN single-crystal substrate tends to be an oriented film.

Methods of evaluating the orientation in the AlN single-crystal substrate according to the present invention include, but are not specifically limited to, known analytical techniques such as the EBSD (Electron Back Scatter Diffraction Patterns) method and X-ray pole figures. For example, when using the EBSD method, an inverse pole figure map and a crystal orientation map of a surface (plate surface) or a cross section orthogonal to the plate surface of the AlN single-crystal substrate are measured. The AlN single-crystal substrate can be defined as being oriented along the two axes in the substantially normal direction and a substantially plate-surface direction, when the following conditions are satisfied: in the obtained inverse pole figure map, (A) the crystals are oriented in a specific orientation (first axis) in the substantially normal direction with respect to the plate surface, and (B) the crystals are oriented in a specific orientation (second axis) in the substantially in-plane plate-surface direction, orthogonal to the first axis; and in the obtained crystal orientation map, (C) the inclination angle from the first axis is distributed within ±10°, and (D) the inclination angle from the second axis is distributed within ±10°. In other words, when the above-described four conditions are satisfied, the AlN single-crystal substrate can be determined as being oriented along the two axes, i.e., the c- and a-axes. For example, when the substantially normal direction with respect to the plate surface is oriented along the c-axis, the substantially in-plane plate-surface direction may be oriented in a specific orientation (for example, the a-axis) orthogonal to the c-axis. While the AlN single-crystal substrate may be oriented along the two axes in the substantially normal direction and the substantially in-plane plate-surface direction, it is preferred that the substantially normal direction is oriented along the c-axis. The smaller the inclination angle distribution in the substantially normal direction and/or the substantially in-plane plate-surface direction, the smaller the mosaicity of the AlN single-crystal substrate; and the closer the inclination angle distribution is to zero, the closer the AlN single-crystal substrate is to a perfect single crystal. Therefore, from the viewpoint of crystallinity of the AlN single-crystal substrate, the inclination angle distribution is preferably smaller in both the substantially normal direction and the substantially plate-surface direction, and is preferably within ±5° or less, and more preferably within ±3° or less, for example.

### Method of Manufacture

The AlN single-crystal substrate of the present invention can be manufactured by various methods as long as the above-described relation concerning the carbon atom concentration C_{C} and the rare earth atom C_{RE} is satisfied. A seed substrate may be provided and then an epitaxial film may be formed thereon, or the AlN single-crystal substrate may be directly manufactured by spontaneous nucleation without using a seed substrate. The seed substrate to be used may be an AlN substrate to achieve homoepitaxial growth, or may be a substrate other than the AlN substrate to achieve heteroepitaxial growth. While any of a vapor phase deposition method, a liquid phase deposition method, and a solid phase deposition method may be used to grow a single crystal, the vapor phase deposition method is preferably used to form an AlN single crystal, and then the seed substrate portion is ground away, as required, to obtain a desired AlN single-crystal substrate. Examples of the vapor phase deposition method include various CVD (chemical vapor deposition) methods (such as thermal CVD, plasma CVD, and MOVPE), a sputtering method, hydride vapor phase epitaxy (HVPE), molecular beam epitaxy (MBE), a sublimation method, and pulsed laser deposition (PLD), with the sublimation method or HVPE being preferred. Examples of the liquid phase deposition method include solution growth methods (such as a flux method). Alternatively, the AlN single-crystal substrate can be obtained without directly forming an AlN single crystal on a seed substrate, by the steps of forming an unoriented precursor layer, forming the unoriented precursor layer into an AlN single-crystal layer by heat treatment, and grinding the seed substrate away. Examples of methods of forming the unoriented precursor layer in this case include an aerosol deposition (AD) method and a hypersonic plasma particle deposition (HPPD) method.

While any of the solid phase deposition method, vapor phase deposition method, and liquid phase deposition method described above may employ known conditions, a technique of fabricating the AlN single-crystal substrate using the sublimation method, for example, is hereinafter described. Specifically, the AlN single-crystal substrate is fabricated by (a) heat-treating polycrystalline AlN powder, (b) forming an AlN single-crystal layer, and (c) grinding a seed substrate away and polishing the surface of the AlN single-crystal layer.

### (a) Heat-Treating Polycrystalline AlN Powder

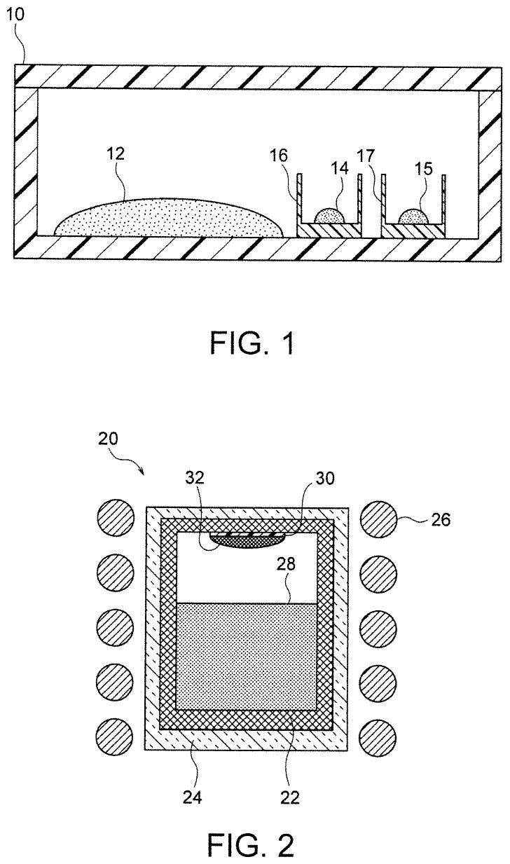

This step is the step of heat-treating polycrystalline AlN powder to obtain AlN raw material powder. As shown in FIG. 1, AlN powder 12 is placed as an AlN single crystal raw material in a sheath 10 and heat-treated in a N₂ atmosphere. Here, graphite powder 14 and rare earth metal oxide (such as Y₂O₃, CaO, CeO₂, Yb₂O₃, or Sm₂O₃) powder 15 are placed in separate crucibles 16 and 17 in the sheath 10, avoiding direct contact with the AlN powder 12. The crucibles 16 and 17 have a size to be accommodated in the sheath 10. Here, by appropriately adjusting the graphite content and the rare earth metal oxide content, an AlN single-crystal substrate satisfying the above-described relation concerning the carbon atom concentration C_{C} and the rare earth atom C_{RE} can be fabricated. The pressure in the furnace in the sheath 10 is preferably 0.1 to 10 atmospheres, and more preferably 0.5 to 5 atmospheres. The heat-treatment temperature is preferably 1900 to 2300° C., and more preferably 2000 to 2200° C. Preferred examples of materials forming the sheath and the crucibles include tantalum carbide, tungsten, molybdenum, and boron nitride (BN), with BN being preferred.

### (b) Forming AlN Single-Crystal Layer

This step is the step of forming an AlN single crystal on a seed substrate in a crystal growth apparatus. FIG. 2 shows one example of the crystal growth apparatus used in the sublimation method. A film formation apparatus 20 shown in FIG. 2 includes a crucible 22, a heat insulating material 24 for heat-insulating the crucible 22, and coils 26 for heating the crucible 22 to a high temperature. The crucible 22 contains AlN raw material powder 28 at a lower portion thereof and has a seed substrate 30 at an upper portion thereof, on which sublimated AlN raw material powder 28 is to be deposited. The crucible 22 is pressurized in an N₂ atmosphere, and the crucible 22 is heated with the coils 26 to sublimate the AlN raw material powder 28. The pressure is preferably 10 to 100 kPa, and more preferably 20 to 90 kPa. Here, a temperature gradient is generated such that the temperature near the seed substrate 30 at the upper portion of the crucible 22 is lower than the temperature near the AlN raw material powder 28 at the lower portion of the crucible 22. For example, a portion of the crucible 22 near the AlN raw material powder 28 is preferably heated to 1900 to 2250° C., and more preferably 2000 to 2200° C.; and a portion of the crucible 22 near the seed substrate 30 is preferably heated to 1400 to 2150° C., and more preferably 1500 to 2050° C. Here, the temperature of the portion near the seed substrate 30 is preferably lower by 100 to 500° C., more preferably 200 to 400° C., than the temperature near the AlN raw material powder 28. Such heating is preferably maintained for 2 to 100 hours, and more preferably 4 to 90 hours. The temperature can be controlled by measuring temperatures at the upper and lower portions of the crucible 22 with a radiation thermometer (not shown) through holes in the heat insulating material 24 covering the crucible 22, and feeding the results back to the temperature adjustment. In this manner, a SiC single crystal is placed as the seed substrate 30, and AlN is re-deposited on the surface of the seed substrate 30 to allow an AlN single-crystal layer 32 to be formed.

### (c) Grinding Seed Substrate Away and Polishing Surface of AlN Single-Crystal Layer

This step includes the grinding step of grinding the seed substrate away to expose the AlN single-crystal layer; and the polishing step of removing irregularities and defects on the surface of the AlN single crystal. The SiC single crystal remains on the AlN single-crystal layer fabricated by the steps (a) and (b) above using the SiC substrate as the seed substrate, and thus, the seed substrate is subjected to grinding to expose the surface of the AlN single-crystal layer. Additionally, to mirror-finish the surface of the formed AlN single-crystal layer, the plate surface is smoothed by lapping with diamond abrasive grains and then polished by chemical mechanical polishing (CMP) with colloidal silica or the like. In this manner, the AlN single-crystal substrate can be fabricated.

### Device

A device can also be fabricated using the AlN single-crystal substrate of the present invention. That is, preferably, a device comprising the AlN single-crystal substrate is provided. Examples of such devices include deep ultraviolet laser diodes, deep ultraviolet diodes, power electronic devices, high-frequency devices, and heat sinks. Methods for manufacturing the device using the AlN single-crystal substrate are not specifically limited, and known techniques may be employed to manufacture the device.

### EXAMPLES

The present invention is described in more detail with the following examples.

### Examples 1 to 17

### (1) Fabrication of AlN Single-Crystal Substrates

### (1a) Heat-Treating Polycrystalline AlN Powder

As shown in FIG. 1, commercially available AlN powder 12 with an average particle diameter of 1 μm used as the AlN single crystal raw material was placed in the BN sheath 10. Commercially available graphite powder 14 with an average particle diameter of 1 μm was added to the BN crucible 16 in the proportions shown in Table 1, relative to 100 parts by weight of the AlN powder, while the rare earth metal oxide powder 15 was added to the BN crucible 17 in the proportions shown in Table 1, relative to 100 parts by weight of the AlN powder. Here, the graphite powder 14 and the rare earth metal oxide powder 15 were not added in Example 7, and the rare earth metal oxide powder 15 was not added in Example 8. As the rare earth metal oxide powder 15, yttrium oxide powder with an average particle diameter of 0.1 μm was used in Examples 1 to 6 and 9 to 14; cerium oxide powder with an average particle diameter of 1 μm was used in Example 15; ytterbium oxide powder with an average particle diameter of 1 μm was used in Example 16; and samarium oxide powder with an average particle diameter of 3 μm was used in Example 17. The BN crucibles 16 and 17 were placed in the BN sheath 10, avoiding direct contact with the AlN powder 12. The BN crucibles 16 and 17 had a size to be accommodated in the sheath 10. The BN sheath 10 was heat-treated in a graphite heater furnace at 2200° C. under 0.1 to 10 atmospheres in a N₂ atmosphere. In this manner, the polycrystalline AlN powder was heat-treated to prepare AlN raw material powder.

### (1b) Forming AlN Single-Crystal Layer

As shown in FIG. 2, the crucible 22 was used as a crystal growth vessel, a circular SiC substrate was mounted as a substrate (seed substrate) 30 in this crucible, and the AlN raw material powder 28 prepared in (1a) above was added avoiding contact with the seed substrate 30. The crucible 22 was pressurized at 50 kPa in a N₂ atmosphere, the portion near the AlN raw material powder 28 in the crucible 22 was heated by high-frequency induction heating to 2100° C., while the portion near the SiC substrate 30 in the crucible 22 was heated to a lower temperature (lower by 200° C.) than that temperature, and the heating was maintained, thereby re-depositing the AlN single-crystal layer 32 on the SiC substrate 30. The heating was maintained for 10 hours.

### (1c) Grinding SiC Substrate Away and Polishing Surface of AlN Single-Crystal Layer

The SiC substrate having AlN re-deposited thereon, obtained in (1b) above, was ground using a grinding wheel of a size up to #2000, until the AlN single crystal was exposed, and the plate surface was further smoothed by lapping with diamond abrasive grains. Then, the plate surface was subjected to chemical mechanical polishing (CMP) with colloidal silica to be mirror-finished. In this manner, a circular AlN single-crystal substrate having a surface area and a thickness as shown in Table 2 was fabricated.

### (2) Evaluation of AlN Single-Crystal Substrate

### (2a) EBSD Measurement

Top and bottom surfaces of the AlN single-crystal substrate were subjected to EBSD measurement. The results showed that the AlN crystals were oriented in both the c- and a-axis directions.

(2b) Concentration of Each Atom within AlN Single-Crystal Substrate

The polished surface of the AlN single-crystal substrate was subjected to dynamic secondary ion mass spectrometry (D-SIMS). The measurement was performed using IMS-7f manufactured by CAMECA as the analytical apparatus, under the following conditions: primary ion species: C_{S}⁺, primary acceleration voltage: 15 kv, and detection range: 25 μm×25 μm. This measurement was performed at 10 measurement points on the polished surface of the AlN single-crystal substrate. These 10 measurement points were defined on the circular substrate surface, as follows: (i) 10 straight lines were drawn radially from the center of the substrate to the outer circumference, so as to divide the circular shape of the substrate into 10 equal parts (i.e., so that adjacent straight lines formed an angle of 36 degrees), and (ii) positions where the distance from the center of the substrate on each of these 10 straight lines is 50% of the radius of the substrate were defined as the measurement points. The average value of each of the carbon atom concentration, oxygen atom concentration, and rare earth atom concentration was measured at a depth of 1 to 3 μm in the substrate, in the 10 measurement points, to calculate the average value of these 10 points. These average values were determined as the carbon atom concentration C_{C} (atoms/cm³), the oxygen atom concentration C_{O} (atoms/cm³), and the rare earth atom concentration C_{RE} (atoms/cm³) in the AlN single-crystal substrate. The ratio of the rare earth atom concentration C_{RE} to the carbon atom concentration C_{C} (C_{RE}/C_{C}) and the difference between the oxygen atom concentration C_{O} and the carbon atom concentration C_{C} (C_{O}−C_{C}) were also determined. In this measurement, the lower detection limit of the carbon atom concentration C_{C} is 1×10¹⁶ atoms/cm³, the lower detection limit of the oxygen atom concentration C_{O} is 5×10¹⁷ atoms/cm³, and the lower detection limit of the rare earth atom concentration C_{RE} is 3×10¹⁵ atoms/cm³. When measured values are below these values, the AlN single-crystal substrate is considered to be substantially free of these atoms. The results are shown in Tables 1 and 2.

### (2c) Examination of Chipping

The surface of the AlN single-crystal substrate after grinding and polishing in (1c) above was observed with an optical microscope to examine for chipping with a maximum length of 50 μm or more. A total of 10 AlN single-crystal substrates were fabricated using the same method as described in (1) above, and it was examined how many of these AlN single-crystal substrates had chipping, and then the AlN single-crystal substrates were rated according to the evaluation criteria shown below. The results are shown in Table 2.

### <Evaluation Criteria>

Rating A: Nine or ten AlN single-crystal substrates were free of chipping
Rating B: Six to eight AlN single-crystal substrates were free of chipping
Rating C: Three to five AlN single-crystal substrates were free of chipping
Rating D: All of the AlN single-crystal substrates showed chipping

TABLE 1

| | | Amount of rare | | | | |
|---|---|---|---|---|---|---|
| | Amount of | earth metal | | | | |
| | graphite powder | oxide powder | | | | |
| | added relative to | added relative to | | | | |
| | 100 parts by | 100 parts by | | | | |
| | weight of AlN | weight of AlN | Carbon atom | Oxygen atom | | |
| | powder | powder | concentration | concentration | | Rare earth atom |
| | (part(s) by | (part(s) by | C_{C} | C_{O} | Type of rare | concentration C_{RE} |
| | weight) | weight) | (atoms/cm³) | (atoms/cm³) | earth atom | (atoms/cm³) |
| Ex. 1 | 6 | 8 | 7.7 × 10¹⁹ | 8.9 × 10¹⁹ | Y | 6.0 × 10¹⁷ |
| Ex. 2 | 6 | 4 | 7.7 × 10¹⁹ | 9.5 × 10¹⁹ | Y | 5.0 × 10¹⁷ |
| Ex. 3 | 6 | 2 | 7.7 × 10¹⁹ | 2.0 × 10²⁰ | Y | 3.0 × 10¹⁷ |
| Ex. 4 | 4 | 4 | 4.0 × 10¹⁹ | 8.9 × 10¹⁹ | Y | 5.0 × 10¹⁷ |
| Ex. 5 | 3 | 1 | 5.0 × 10¹⁸ | 3.0 × 10²⁰ | Y | 9.0 × 10¹⁶ |
| Ex. 6 | 3 | 4 | 5.0 × 10¹⁸ | 8.9 × 10¹⁹ | Y | 5.5 × 10¹⁷ |
| Ex. 7* | 0 | 0 | 8.0 × 10¹⁷ | 5.0 × 10²⁰ | — | below the lower |
| | | | | | | detection limit |
| Ex. 8* | 2 | 0 | 1.0 × 10¹⁸ | 5.0 × 10²⁰ | — | below the lower |
| | | | | | | detection limit |
| Ex. 9* | 10 | 60 | 5.0 × 10²⁰ | 6.0 × 10¹⁹ | Y | 1.1 × 10²⁰ |
| Ex. 10* | 12 | 4 | 7.0 × 10²⁰ | 8.0 × 10¹⁹ | Y | 5.0 × 10¹⁷ |
| Ex. 11 | 15 | 90 | 8.0 × 10²⁰ | below the | Y | 1.5 × 10²⁰ |
| | | | | lower | | |
| | | | | detection limit | | |
| Ex. 12 | 6 | 8 | 7.7 × 10¹⁹ | 8.9 × 10¹⁹ | Y | 6.0 × 10¹⁷ |
| Ex. 13 | 6 | 8 | 7.7 × 10¹⁹ | 8.9 × 10¹⁹ | Y | 6.0 × 10¹⁷ |
| Ex. 14 | 6 | 8 | 7.7 × 10¹⁹ | 8.9 × 10¹⁹ | Y | 6.0 × 10¹⁷ |
| Ex. 15 | 6 | 8 | 7.7 × 10¹⁹ | 9.1 × 10¹⁹ | Ce | 6.0 × 10¹⁷ |
| Ex. 16 | 6 | 8 | 7.7 × 10¹⁹ | 9.4 × 10¹⁹ | Yb | 6.0 × 10¹⁷ |
| Ex. 17 | 6 | 8 | 7.7 × 10¹⁹ | 9.9 × 10¹⁹ | Sm | 6.0 × 10¹⁷ |

*indicates comparative examples.

TABLE 2

| | | Difference | | | |
|---|---|---|---|---|---|
| | | between | | | |
| | | oxygen atom | | | |
| | Ratio of rare | concentration | | | |
| | earth atom | and | | Thick- | |
| | concentration | carbon atom | Surface | ness | Exami- |
| | to carbon atom | concentration | area of | of | nation |
| | concentration | C_{O} − C_{C} | substrate | substrate | of |
| | C_{RE}/C_{C} | (atoms/cm³) | (mm²) | (mm) | chipping |
| Ex. 1 | 0.0078 | 1.2 × 10¹⁹ | 2026 | 0.40 | A |
| Ex. 2 | 0.0065 | 1.8 × 10¹⁹ | 2026 | 0.40 | A |
| Ex. 3 | 0.0039 | 1.2 × 10²⁰ | 2026 | 0.40 | A |
| Ex. 4 | 0.0125 | 4.9 × 10¹⁹ | 2026 | 0.40 | B |
| Ex. 5 | 0.0180 | 3.0 × 10²⁰ | 2026 | 0.40 | C |
| Ex. 6 | 0.1100 | 8.4 × 10¹⁹ | 2026 | 0.40 | C |
| Ex. 7* | — | 5.0 × 10²⁰ | 2026 | 0.40 | D |
| Ex. 8* | — | 5.0 × 10²⁰ | 2026 | 0.40 | D |
| Ex. 9* | 0.2200 | −4.4 × 10²⁰ | 2026 | 0.40 | D |
| Ex. 10* | 0.0007 | −6.2 × 10²⁰ | 2026 | 0.40 | D |
| Ex. 11 | 0.1875 | — | 2026 | 0.40 | C |
| Ex. 12 | 0.0078 | 1.2 × 10¹⁹ | 8103 | 0.40 | B |
| Ex. 13 | 0.0078 | 1.2 × 10¹⁹ | 79 | 0.40 | A |
| Ex. 14 | 0.0078 | 1.2 × 10¹⁹ | 2026 | 0.70 | A |
| Ex. 15 | 0.0078 | 1.4 × 10¹⁹ | 2026 | 0.40 | B |
| Ex. 16 | 0.0078 | 1.7 × 10¹⁹ | 2026 | 0.40 | B |
| Ex. 17 | 0.0078 | 2.2 × 10¹⁹ | 2026 | 0.40 | B |

*indicates comparative examples.

What is claimed is:

1. An AlN single-crystal substrate comprising a carbon atom and a rare earth atom as impurities, the AlN single-crystal substrate satisfying a relation:
0.0010<C_{RE}/C_{C}<0.2000
wherein C_{C} is a carbon atom concentration (atoms/cm³) and C_{RE} is a rare earth atom concentration (atoms/cm³) in the AlN single-crystal substrate.

2. The AlN single-crystal substrate according to claim 1, wherein the AlN single-crystal substrate comprises an oxygen atom as an impurity and satisfies a relation:
4.5×10¹⁸<C_{O}−C_{C}<9.0×10²¹
wherein C_{O} is an oxygen atom concentration (atoms/cm³) in the AlN single-crystal substrate.

3. The AlN single-crystal substrate according to claim 1, wherein the AlN single-crystal substrate has a surface area of more than 75 mm² and less than 18500 mm², and has a thickness of more than 0.10 mm and less than 1.00 mm.

4. The AlN single-crystal substrate according to claim 1, wherein the AlN single-crystal substrate comprises an oxygen atom as an impurity and satisfies relations:
4.0×10¹⁸<C_{C}<4.0×10²¹,
4.0×10¹⁸<C_{O}<4.0×10²¹, and
1.0×10¹⁶<C_{RE}<1.0×10¹⁹
wherein C_{O} is an oxygen atom concentration (atoms/cm³) in the AlN single-crystal substrate.

5. The AlN single-crystal substrate according to claim 1, wherein the rare earth atom is an Y atom.

6. A device comprising the AlN single-crystal substrate according to claim 1.
